(19) United States
(12) Patent Application Publication
(10) Pub. No.: US 2025/0139788 A1
(43) Pub. Date: May 1, 2025

(54) DEEP LEARNING-BASED FOREGROUND MASKING

(71) Applicant: Hyperfine Operations, Inc., Guilford, CT (US)

(72) Inventors: David Edmunds, Branford, CT (US); Jo Schlemper, Long Island City, NY (US); Michal Sofka, Princeton, NJ (US)

(73) Assignee: Hyperfine Operations, Inc., Guilford, CT (US)

(21) Appl. No.: 19/009,533

(22) Filed: Jan. 3, 2025

Related U.S. Application Data
(63) Continuation of application No. PCT/US2023/069656, filed on Jul. 5, 2023.
(60) Provisional application No. 63/358,817, filed on Jul. 6, 2022.

(51) Int. Cl. G06T 7/194

(52) U.S. Cl. CPC G06T 7/194; G06T 2207/10088; G06T 2207/20084

(57) ABSTRACT

Systems and methods for training and deploying machine learning segmentation models to produce foreground masks of images are provided. The model may be used to generate foreground masks. A first method includes receiving images and annotations indicative of which pixels are in the foregrounds of the images, and generating, based on the images and the annotations, a model configured to receive, as input, a subject image and provide, as output, one or more probability maps indicative of foreground probabilities for pixels in the subject image. A foreground probability is indicative of a likelihood that the pixel is part of a foreground object or artifact in the image. Another method includes receiving a subject image, and generating a foreground mask for the subject image at least in part by applying a machine learning model to the subject image, the model having been generated based on disclosed training methods.

### CROSS-REFERENCE TO RELATED PATENT APPLICATIONS

This application is a bypass continuation of international application PCT/US2023/069656, filed Jul. 5, 2023, which claims the benefit of and priority to U.S. Provisional Patent Application 63/358,817 filed Jul. 6, 2022, each which is incorporated herein by reference in its entirety.

### FIELD

The present invention relates generally to distinguishing objects and/or artifacts in foregrounds and/or backgrounds of images. For example, the disclosure provides a deep learning-based approach to obtaining a machine learning model for characterizing pixels in images and generating foreground masks that may include various objects and/or artifacts, and may exclude background regions, in medical images such as magnetic resonance (MR) images.

### BACKGROUND

Medical imaging systems may be utilized to generate images of the inside of the human body. Magnetic resonance imaging (MRI) systems, for example, may be used to detect MR signals in response to applied electromagnetic fields. The MR signals produced by MRI systems may be processed to construct MR images, which may enable observation of internal anatomy for diagnostic or research purposes. Not all regions of a medical image, however, are relevant or contain useful information. For example, a background region of a medical image can usually be ignored because it does not include any structures of interest.

### SUMMARY OF THE INVENTION

Various embodiments of the disclosure relate to a method that may comprise receiving images and annotations indicative of which pixels are in the foregrounds of the images, and generating, based on the images and the annotations, a machine learning model. The machine learning model may be configured to receive, as input, an image and provide, as output, one or more probability maps indicative of foreground probabilities for pixels in the image, wherein a foreground probability for a pixel is indicative of a likelihood that the pixel is part of a foreground object or artifact in the image.

In example embodiments, generating the machine learning model comprises minimizing validation loss over a plurality of epochs.

In example embodiments, the validation loss is a cross-entropy loss.

In example embodiments, the annotated images comprise annotated magnetic resonance (MR) images generated based on a plurality of sequence types.

In example embodiments, the plurality of sequence types comprises at least one of diffusion-weighted imaging (DWI), T1, T2, or fluid attenuated inversion recovery (FLAIR).

In example embodiments, the plurality of sequence types comprises a plurality of DWI, T1, T2, and/or FLAIR.

In example embodiments, the method further comprises deploying the machine learning model to generate a foreground mask for a subject image.

In example embodiments, deploying the machine learning model comprises applying the machine learning model to the subject image, and thresholding foreground probabilities for pixels in the subject image to obtain the foreground mask.

In example embodiments, generating the machine learning model comprises applying a machine learning technique to the images and the annotations, and optimizing a parameter of the machine learning model.

In example embodiments, the machine learning model comprises a neural network.

In example embodiments, the neural network is a residual neural network-based machine learning model.

Various embodiments of the invention relate to a method that may comprise: receiving a subject image, and generating a foreground mask for the subject image. The foreground mask may be generated at least in part by applying a machine learning model to the subject image, the machine learning model having been generated based on training images and annotations distinguishing between pixels in the foregrounds of the training images and pixels in the backgrounds of the training images, the machine learning model being configured to receive, as input, the subject image and provide, as output, one or more probability maps indicative of foreground probabilities for pixels in the subject image, wherein a foreground probability for a pixel is indicative of a likelihood that the pixel is part of a foreground object or artifact in the subject image.

In example embodiments, generating the foreground mask further comprises thresholding foreground probabilities for pixels in the MR image to obtain the foreground mask.

In example embodiments, the foreground mask is a binary foreground mask.

In example embodiments, the machine learning model comprises a neural network.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects may be combined and it will be readily appreciated that features described in the context of one aspect of the present disclosure may be combined with other aspects. Aspects may be implemented in any convenient form. In a non-limiting example, by appropriate computer programs, which may be carried on appropriate carrier media (computer readable media), which may be tangible carrier media (e.g. disks) or intangible carrier media (e.g. communications signals). Aspects may also be implemented using suitable apparatus, which may take the form of programmable computers running computer programs arranged to implement the aspect. As used in the specification and in the claims, the singular form of “a,” “an,” and “the” include plural referents unless the context clearly dictates otherwise.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1A illustrates example components of a magnetic resonance imaging system, in accordance with one or more implementations;

FIG. 1B illustrates an example system for training a segmentation model to generate probability maps useful in producing masks of subject images, in accordance with one or more implementations;

FIG. 2 depicts an example data flow diagram of an example segmentation model training process, in accordance with one or more implementations;

FIG. 3 depicts an example data flow diagram of an example segmentation model deployment process, in accordance with one or more implementations;

FIG. 4 depicts a flowchart of an example method of training a segmentation model and deploying it to produce a probability map useful in producing a foreground mask of a subject image, in accordance with one or more implementations;

FIG. 5 depicts a magnetic resonance image and a foreground mask of the magnetic resonance image produced according to one of the methods or processes described herein;

FIG. 6 shows example experimental data comparing approaches to foreground mask generation, in accordance with one or more implementations; and

FIG. 7 is a block diagram of an example computing system suitable for use in the various arrangements described herein, in accordance with one or more example implementations.

### DETAILED DESCRIPTION

Below are detailed descriptions of various concepts related to and implementations of techniques, approaches, methods, apparatuses, and systems for training and deploying machine learning models for generation of foreground masks for medical images. The various concepts introduced above and discussed in detail below may be implemented in any of numerous ways, as the described concepts are not limited to any particular manner of implementation. Examples of specific implementations and applications are provided primarily for illustrative purposes.

Medical imagers, such as magnetic resonance imaging (MRI) systems, computerized tomography (CT) systems, positron emission tomography (PET) systems, and ultrasound systems, can generate images for health evaluation. MR images, for example, are generated by “scanning” a patient while the MRI system applies magnetic fields to the patient and particular data is captured. Medical scans produce raw scan data that can be transformed or otherwise processed into an image that can then be analyzed or reviewed to better evaluate a patient's health.

During image processing, it may be useful to isolate an object being imaged in the foreground, from the surrounding regions, the background. This can be achieved by generating a foreground mask that, when overlaid on or superimposed with a medical image, visually distinguishes the foreground from the background. A foreground mask can be a binary image, distinguishing between two regions or states of an image: foreground and background. A binary foreground mask represents the spatial layout of the object being imaged by assigning, for example, a value of 1 to foreground pixels and a value of 0 to background pixels, or vice-versa. A foreground region may be a “complement” of a background region when every pixel in an image is considered to be either in the foreground of an image or in the background of the image, such that pixels not considered to be foreground pixels are considered to be background pixels, and vice-versa. Other binary masks may distinguish between the presence of an object or artifact (whether in the foreground of the image or the background of the image), and a lack or absence of the object or artifact in the image. Non-binary masks can indicate more than two regions or states, such as, for example, a first region or state corresponding to background, a second region or state corresponding to foreground, a third region or state corresponding to a particular object or artifact in the foreground, and optionally, a fourth region or state corresponding to a particular object or artifact in the background.

Prior approaches to producing a foreground mask each have their deficiencies. One such approach is to create masks manually. For example, an expert may analyze an MR image and, using specialized software tools, separate the foreground from the background based on their expert judgment (by, e.g., drawing a perimeter of a foreground region or structure of interest in the image), and a foreground mask may be generated accordingly. This is expensive, time consuming, and prone to human error. Alternatively, a thresholding technique may be applied to an MR image to automatically produce a foreground mask of the MR image. Thresholding divides an image into foreground and background regions based on a threshold intensity value. Each pixel in the image is compared to the threshold value. If the pixel intensity meets or exceeds the threshold, the pixel is assigned to the foreground. If the pixel intensity value is below the threshold, it is assigned to the background. While efficient and automatic, thresholding techniques produce foreground masks that tend to be less accurate than those produced manually by experts. Because thresholding techniques rely solely on pixel intensity values, low intensity pixels in the foreground of an MR image may be classified as background pixels, and conversely, high intensity pixels in the background of an MR image may be classified as foreground pixels.

Machine-learning techniques can be used to teach a computer to perform tasks without having to specifically program the computer to perform those tasks. This is especially useful when, for example, the number of possible variations in what the tasks are to be performed on, and/or how the tasks are to be performed, is not readily definable. A thresholding approach as discussed above, for example, only considers one variable (e.g., pixel intensity), and does not take into account other factors that affect the outcome (e.g., whether a pixel is in the foreground or background despite intensity value).

One machine-learning approach is referred to as “deep learning” and is based on multiple layers or stages of artificial neural networks. In various embodiments, the technical solution disclosed herein may employ deep learning to train a machine learning model to generate foreground masks of MR and other image modalities. A training process may be performed to train the machine learning model using training data comprising, for example, images annotated to distinguish or identify foregrounds, backgrounds, and/or certain features (e.g., objects and/or artifacts) in the foregrounds and/or backgrounds. The annotations may be based on, for example, expert evaluation of the training images. The training images may include, without limitation, medical images (e.g., MR images, CT images, etc.) as well as natural images (e.g., images captured using non-medical imaging devices). Once the machine learning model is trained, it may be applied to images for which a foreground mask is required. The solution described herein provides greater accuracy compared to other approaches to generating foreground masks of images, and it provides greater computational efficiency. Accordingly, the systems and methods described herein provide technical improvements to image processing in general, and mask generation in particular.

As used herein, a “foreground” of an image corresponds to a region of interest (ROI) being imaged (e.g., a patient's head), and excludes other regions that extend beyond the ROI in the image. As used herein, a “foreground probability” is indicative of a likelihood that a pixel is part of a foreground, an object, or an artifact. A probability may be a first likelihood that a pixel is in the background of an image, and the first likelihood is indicative of a second likelihood that the pixel is in the foreground because subtracting the first likelihood from 100% would provide the second likelihood. Similarly, a probability may be a third likelihood that a pixel is part of, or not part of, an object or an artifact in the image being analyzed or processed. A foreground probability, as used herein, can indicate a likelihood that a pixel is part of a background of an image. A background probability may thus be used instead of, or in addition to, a foreground probability. In such a case, a background probability may be indicative of a likelihood a pixel is part of the foreground, by subtracting the background probability from 100%, for example.

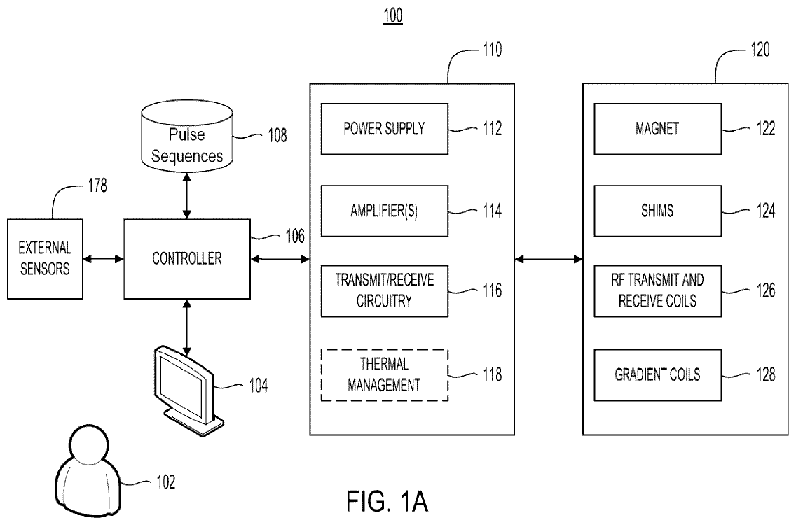

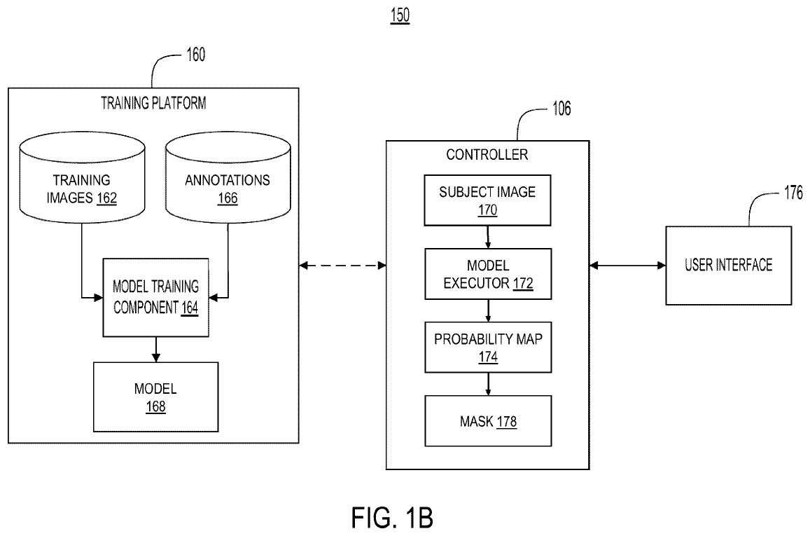

FIG. 1A illustrates an example MRI system which may be used with the segmentation models trained using the techniques described herein. In FIG. 1A, MRI system 100 may include a computing device 104, a controller 106, a pulse sequences repository 108, a power management system 110, and magnetics components 120. The MRI system 100 is illustrative, and an MRI system may have one or more other components of any suitable type in addition to or instead of the components illustrated in FIG. 1A. Additionally, the implementation of components for a particular MRI system may differ from those described herein. Examples of low-field MRI systems may include portable MRI systems, which may have a field strength that is, in a non-limiting example, less than or equal to 0.5 T, that is less than or equal to 0.2 T, that is within a range from 1 mT to 100 mT, that is within a range from 50 mT to 0.1 T, that is within a range of 40 mT to 80 mT, that is about 64 mT, etc. In various embodiments, the disclosed approach may be implemented with portable MRI systems that employ low magnetic field strengths (e.g., that is less than about 0.5 T, that is less than about 0.2 T, that is between about 100 mT and about 400 mT, that is between about 200 mT and about 300 mT, that is between about 1 mT and 100 mT, that is between about 50 mT and about 100 mT, that is between about 40 mT and about 80 mT, that is about 64 mT, etc.) for imaging of subjects. The portable MRI systems may be transportable from one area in a room to another area of a room, and/or from one room to another room. Such portable MRI systems may comprise power components that allow for the MRI system to be connected to mains power sources (e.g., via power outlets commonly available in healthcare facilities), and be sized so as to be able to pass through doors and other entryways through which the MRI system might be transported.

The magnetics components 120 may include B₀ magnets 122, shims 124, radio frequency (RF) transmit and receive coils 126, and gradient coils 128. The B₀ magnets 122 may be used to generate a main magnetic field B₀. B₀ magnets 122 may be any suitable type or combination of magnetics components that may generate a useful main magnetic B₀ field. In some embodiments, B₀ magnets 122 may be one or more permanent magnets, one or more electromagnets, one or more superconducting magnets, or a hybrid magnet comprising one or more permanent magnets and one or more electromagnets or one or more superconducting magnets. In some embodiments, B₀ magnets 122 may be configured to generate a B₀ magnetic field having a field strength that is less than or equal to 0.2 T or within a range from 50 mT to 0.1 T.

In some implementations, the B₀ magnets 122 may include a first and second B₀ magnet, which may each include permanent magnet blocks arranged in concentric rings about a common center. The first and second B₀ magnet may be arranged in a bi-planar configuration such that the imaging region may be located between the first and second B₀ magnets. In some embodiments, the first and second B₀ magnets may each be coupled to and supported by a ferromagnetic yoke configured to capture and direct magnetic flux from the first and second B₀ magnets.

The gradient coils 128 may be arranged to provide gradient fields and, in a non-limiting example, may be arranged to generate gradients in the B₀ field in three substantially orthogonal directions (X, Y, and Z). Gradient coils 128 may be configured to encode emitted MR signals by systematically varying the B₀ field (the B₀ field generated by the B₀ magnets 122 or shims 124) to encode the spatial location of received MR signals as a function of frequency or phase. In a non-limiting example, the gradient coils 128 may be configured to vary frequency or phase as a linear function of spatial location along a particular direction, although more complex spatial encoding profiles may also be provided by using nonlinear gradient coils. In some embodiments, the gradient coils 128 may be implemented using laminate panels (e.g., printed circuit boards), in a non-limiting example.

MRI scans are performed by exciting and detecting emitted MR signals using transmit and receive coils, respectively (referred to herein as radio frequency (RF) coils). The transmit and receive coils may include separate coils for transmitting and receiving, multiple coils for transmitting or receiving, or the same coils for transmitting and receiving. Thus, a transmit/receive component may include one or more coils for transmitting, one or more coils for receiving, or one or more coils for transmitting and receiving. The transmit/receive coils may be referred to as Tx/Rx or Tx/Rx coils to generically refer to the various configurations for transmit and receive magnetics components of an MRI system. These terms are used interchangeably herein. In FIG. 1A, RF transmit and receive coils 126 may include one or more transmit coils that may be used to generate RF pulses to induce an oscillating magnetic field B₁. The transmit coil(s) may be configured to generate any type of suitable RF pulses.

The power management system 110 includes electronics to provide operating power to one or more components of the MRI system 100. In a non-limiting example, the power management system 110 may include one or more power supplies, energy storage devices, gradient power components, transmit coil components, or any other suitable power electronics needed to provide suitable operating power to energize and operate components of MRI system 100. As illustrated in FIG. 1A, the power management system 110 may include a power supply system 112, amplifier(s) 114, transmit/receive circuitry 116, and may optionally include thermal management components 118 (e.g., cryogenic cooling equipment for superconducting magnets, water cooling equipment for electromagnets).

The power supply system 112 may include electronics that provide operating power to magnetics components 120 of the MRI system 100. The electronics of the power supply system 112 may provide, in a non-limiting example, operating power to one or more gradient coils (e.g., gradient coils 128) to generate one or more gradient magnetic fields to provide spatial encoding of the MR signals. Additionally, the electronics of the power supply system 112 may provide operating power to one or more RF coils (e.g., RF transmit and receive coils 126) to generate or receive one or more RF signals from the subject. In a non-limiting example, the power supply system 112 may include a power supply configured to provide power from mains electricity to the MRI system or an energy storage device. The power supply may, in some embodiments, be an AC-to-DC power supply that converts AC power from mains electricity into DC power for use by the MRI system. The energy storage device may, in some embodiments, be any one of a battery, a capacitor, an ultracapacitor, a flywheel, or any other suitable energy storage apparatus that may bi-directionally receive (e.g., store) power from mains electricity and supply power to the MRI system. Additionally, the power supply system 112 may include additional power electronics including, but not limited to, power converters, switches, buses, drivers, and any other suitable electronics for supplying the MRI system with power.

The amplifiers(s) 114 may include one or more RF receive (Rx) pre-amplifiers that amplify MR signals detected by one or more RF receive coils (e.g., coils 126), one or more RF transmit (Tx) power components configured to provide power to one or more RF transmit coils (e.g., coils 126), one or more gradient power components configured to provide power to one or more gradient coils (e.g., gradient coils 128), and may provide power to one or more shim power components configured to provide power to one or more shims (e.g., shims 124). In some implementations, the shims 124 may be implemented using permanent magnets, electromagnetics (e.g., a coil), or combinations thereof. The transmit/receive circuitry 116 may be used to select whether RF transmit coils or RF receive coils are being operated.

As illustrated in FIG. 1A, the MRI system 100 may include the controller 106 (also referred to as a console), which may include control electronics to send instructions to and receive information from power management system 110. The controller 106 may be configured to implement one or more pulse sequences, which are used to determine the instructions sent to power management system 110 to operate the magnetics components 120 in a desired sequence (e.g., parameters for operating the RF transmit and receive coils 126, parameters for operating gradient coils 128, etc.). A pulse sequence may generally describe the order and timing in which the RF transmit and receive coils 126 and the gradient coils 128 operate to acquire resulting MR data. In a non-limiting example, a pulse sequence may indicate an order and duration of transmit pulses, gradient pulses, and acquisition times during which the receive coils acquire MR data.

A pulse sequence may be organized into a series of periods. In a non-limiting example, a pulse sequence may include a pre-programmed number of pulse repetition periods, and applying a pulse sequence may include operating the MRI system in accordance with parameters of the pulse sequence for the pre-programmed number of pulse repetition periods. In each period, the pulse sequence may include parameters for generating RF pulses (e.g., parameters identifying transmit duration, waveform, amplitude, phase, etc.), parameters for generating gradient fields (e.g., parameters identifying transmit duration, waveform, amplitude, phase, etc.), timing parameters governing when RF or gradient pulses are generated or when the receive coil(s) are configured to detect MR signals generated by the subject, among other functionality. In some embodiments, a pulse sequence may include parameters specifying one or more navigator RF pulses, as described herein.

Examples of pulse sequences include zero echo time (ZTE) pulse sequences, balance steady-state free precession (bSSFP) pulse sequences, gradient echo pulse sequences, inversion recovery pulse sequences, diffusion weighted imaging (DWI) pulse sequences, spin echo pulse sequences including conventional spin echo (CSE) pulse sequences, fast spin echo (FSE) pulse sequences, turbo spin echo (TSE) pulse sequences or any multi-spin echo pulse sequences such as diffusion weighted spin echo pulse sequences, inversion recovery spin echo pulse sequences, arterial spin labeling pulse sequences, and Overhauser imaging pulse sequences, among others.

As illustrated in FIG. 1A, the controller 106 may communicate with the computing device 104, which may be programmed to process received MR data. In a non-limiting example, the computing device 104 may process received MR data to generate one or more MR images using any suitable image reconstruction processes, including the execution of segmentation models trained using the techniques described herein.

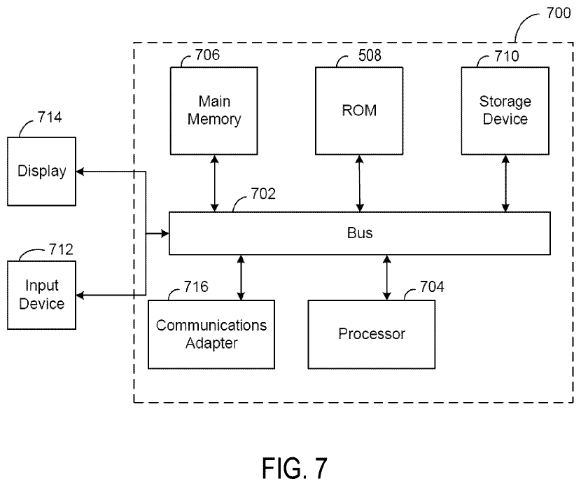

The computing device 104 may be any electronic device configured to process acquired MR data and generate one or more images of a subject being imaged. The computing device 104 may include at least one processor and a memory (e.g., a processing circuit). The memory may store processor-executable instructions that, when executed by a processor, cause the processor to perform one or more of the operations described herein. The processor may include a microprocessor, an application-specific integrated circuit (ASIC), a field-programmable gate array (FPGA), a graphics processing unit (GPU), a tensor processing unit (TPU), etc., or combinations thereof. The memory may include, but is not limited to, electronic, optical, magnetic, or any other storage or transmission device capable of providing the processor with program instructions. The memory may further include a floppy disk, CD-ROM, DVD, magnetic disk, memory chip, ASIC, FPGA, read-only memory (ROM), random-access memory (RAM), electrically erasable programmable ROM (EEPROM), erasable programmable ROM (EPROM), flash memory, optical media, or any other suitable memory from which the processor may read instructions. The instructions may include code generated from any suitable computer programming language. The computing device 104 may include any or all of the components and perform any or all of the functions of the computer system 700 described in connection with FIG. 7. In some implementations, the computing device 104 may be located in a same room as the MRI system 100 or coupled to the MRI system 100 via wired or wireless connection.

In some implementations, computing device 104 may be a fixed electronic device such as a desktop computer, a server, a rack-mounted computer, or any other suitable fixed electronic device that may be configured to process MR data and generate one or more images of the subject being imaged. Alternatively, computing device 104 may be a portable device such as a smart phone, a personal digital assistant, a laptop computer, a tablet computer, or any other portable device that may be configured to process MR data and generate one or more images of the subject being imaged. In some implementations, computing device 104 may comprise multiple computing devices of any suitable type, as aspects of the disclosure provided herein are not limited in this respect. In some implementations, operations that are described as being performed by the computing device 104 may instead be performed by the controller 106, or vice-versa. In some implementations, certain operations may be performed by both the controller 106 and the computing device 104 via communications between said devices.

The MRI system 100 may include one or more external sensors 178. The one or more external sensors may assist in detecting one or more error sources (e.g., motion, noise) which degrade image quality. The controller 106 may be configured to receive information from the one or more external sensors 178. In some embodiments, the controller 106 of the MRI system 100 may be configured to control operations of the one or more external sensors 178, as well as collect information from the one or more external sensors 178. The data collected from the one or more external sensors 178 may be stored in a suitable computer memory and may be utilized to assist with various processing operations of the MRI system 100.

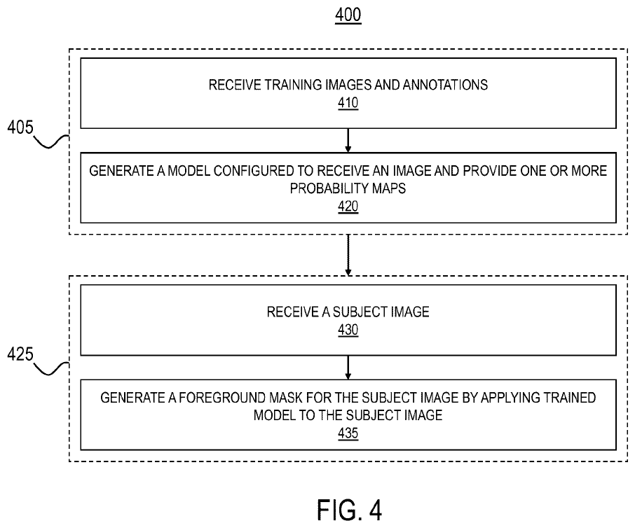

FIG. 1B illustrates an example system 150 for training a segmentation model, in accordance with one or more implementations. In a non-limiting example, the system 150 may be used to perform all or part of the example method 400 described in connection with FIG. 4, as well as any other operations described herein. In some implementations, the system 150 forms a portion of an MRI system, such as MRI system 100 described in connection with FIG. 1A. In some implementations, the system 150 may be external to an MRI system but communicates with the MRI system (or components thereof) to perform the example method 400 of FIG. 4 as described herein.

As shown in FIG. 1B, an embodiment of the example system 150 may include the controller 106, a training platform 160, and a user interface 176. The user interface 176 may present or enable inspection of any of the reconstructed MR images utilized by the techniques described herein. The user interface 176 may provide input relating to the performance of such techniques, in a non-limiting example, by receiving input or configuration data relating to the training process, MR scans, or MR image reconstruction. The user interface 176 may allow a user to select a type of imaging to be performed by the MRI system (e.g., diffusion-weighted imaging, etc.), select a sampling density for the MR scan, or to define any other type of parameter relating to MR imaging or model training as described herein. The user interface 176 may allow a user to initiate imaging by the MRI system, or to execute or coordinate any of the machine-learning techniques described herein.

The training platform 160 may be, or may include, the computing device 104 of FIG. 1A. Alternatively, the training platform 160 (or any components thereof) may be implemented as part of the controller 106. The training platform 160 may include at least one processor and a memory (e.g., a processing circuit). The memory may store processor-executable instructions that, when executed by a processor, cause the processor to perform one or more of the operations described herein. The processor may include a microprocessor, an ASIC, an FPGA, a GPU, a TPU, etc., or combinations thereof. The memory may include, but is not limited to, electronic, optical, magnetic, or any other storage or transmission device capable of providing the processor with program instructions. The memory may further include a floppy disk, CD-ROM, DVD, magnetic disk, memory chip, ASIC, FPGA, ROM, RAM, EEPROM, EPROM, flash memory, optical media, or any other suitable memory from which the processor may read instructions. The instructions may include code generated from any suitable computer programming language. The training platform 160 may include any or all of the components and perform any or all of the functions of the computer system 700 described in connection with FIG. 7. In some implementations, the training platform 160 may be a desktop computer, a server, a rack-mounted computer, a distributed computing environment, or any other computing system that may be configured to train the machine-learning model 168 using the training techniques described herein. The training platform 160 may include any number of computing devices of any suitable type.

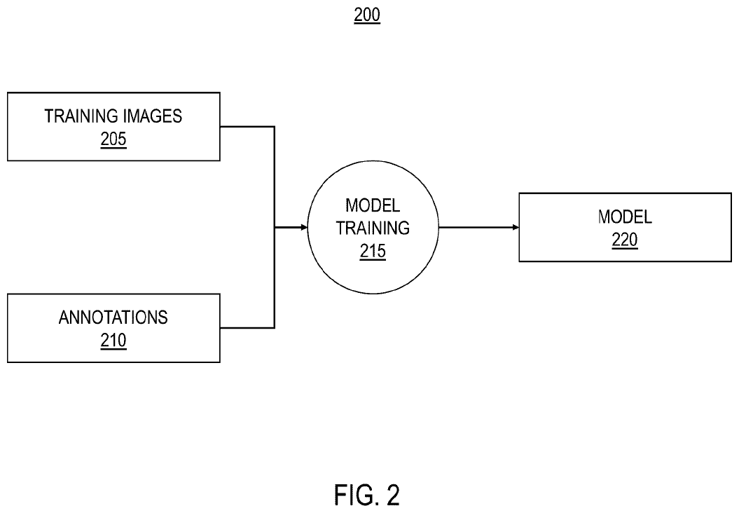

The training platform 160 may include training images 162, annotations of the training images 166, a model training component 164, and a model 168 (e.g., which may be trained and retrained as described herein by the model training component 164). The model training component 164 may be implemented using any suitable combination of software or hardware. Additionally or alternatively, the model training component 164 may be implemented by one or more servers or distributed computing systems, which may include a cloud computing system. In some implementations, the model training component 164 may be implemented using one or more virtual servers or computing systems. The model training component 164 may implement the example model training process 200 described in connection with FIG. 2, to train the model 168.

The model training component 164 may utilize the training images 162 and annotations 166 of the training images 162 to train the model 168, as described herein. The training images may be natural images, MR images, and/or other types of medical images. The training images 162 may be two-, three-, or four-dimensional images. For example, for four-dimensional images, the first three dimensions may define shape and position in space and the fourth dimension may define shape and position in time. The training images 162 may also be one-dimensional projections of higher dimensional images. The training images 162 may be isotropic or anisotropic, that is, the space between adjacent pixels in each training image may be the same along each axis, or the space between adjacent pixels along one or more axes may be different than the space along one or more other axes.

In some implementations, the training images 162 comprise MR images generated based on a plurality of sequence types (e.g., diffusion weighted (DWI), T1 weighted (T1), T2 weighted (T2), or fluid attenuation inversion recovery (FLAIR) sequence types). In some implementations, the training images 162 comprise images and one or more affine transforms of the images. The images may be oriented uniformly. In some implementations, the images are oriented to left posterior superior (LPS) orientation in right anterior superior (RAS) coordinate space. The training images 162 may be uniformly sized. Each image may be resized from an initial size to the uniform size. For example, if the training images 162 are two-dimensional, the uniform size may be between 32×32 and 1000×1000. If the training images 162 are three-dimensional, the uniform size may be between 32×32×32 and 1000×1000×1000. If the training images 162 are four-dimensional, the uniform size may be between 32×32×32×32 and 1000×1000×1000×1000. In some implementations, the uniform size may be 96×96, 96×96×96, or 96×96×96×96.

The annotations 166 may characterize the pixels of the training images 162. The annotations 166 may, for each image of the training images 162, identify which of a plurality of segments of the image particular pixels belong. In some implementations, the annotations 166 may identify which pixels in an image are foreground pixels and which pixels in an image are background pixels. In some implementations, the annotations 166 may identify a pixel as belonging to the foreground of an image, the background of the image, or a particular object or artifact in the foreground or background of the image. In some implementations, the annotations 166 may comprise segmentation masks (e.g., foreground masks) of the training images. The segmentation masks may be manually created by expert analysis of the training images.

The model training component 164 may perform any of the functionality described herein to train the model 168. For example, using the training images 162 and the annotations 166, the model training component 164 may train an initial model using a suitable training technique. The initial model may be a machine-learning model. The machine learning model may comprise a neural network. In one implementation the initial model may comprise a residual neural network-based model. In other implementations, the model may comprise other networks. The initial model may be configured to receive, as input, an image (e.g., an MR image) and provide, as output, one or more probability maps indicative of foreground probabilities for pixels in the image. A foreground probability for a pixel may be indicative of a likelihood that the pixel is part of a foreground, a background, an object, or an artifact in the image.

In example embodiments, the model 168 may be configured to output a single probability map indicative of a single probability. In other embodiments, the model 168 may be configured to output multiple probability maps or a single probability map with multiple channels or dimensions, where each map, channel, or dimension is indicative of different probabilities. For example, the model 168 may be configured to output a probability map having two channels, or dimensions, a first channel, or dimension, indicative of the foreground probabilities of an input image's pixels and a second channel, or dimension, indicative of the background probabilities of the input image's pixels. In other example embodiments, the model 168 may be configured to output a probability map having three or more channels, or dimensions, where a first channel, or dimension, is indicative of the foreground probabilities of an input image's pixels and a second channel, or dimension, is indicative of the background probabilities of the input image's pixels, and the other channels, or dimensions, indicative of the likelihood that the input image's pixels belong to a third category, for example, the likelihood that they belong to a structure or an artifact in the image. Instead of the multichannel, or multidimensional, probability maps described in the foregoing examples, the model 168 may be configured to output multiple probability maps, where each map is indicative of different probabilities of the input image's pixels.

In some embodiments, the model 168 may be configured, or trained, so that the probabilities indicated by two or more of a probability map's channels, or two or more probability maps, compliment each other. For example, if the model 168 is configured to output a two dimensional probability map where the first channel is indicative of foreground probabilities and the second channel is indicative of background probabilities, the model may be configured or trained such that for any pixel in an input image, the foreground probability and the background probability of that pixel sum to 1, or 100%, indicating that the pixel has a 100% likelihood of being either in the foreground or the background of the input image.

The model training component 164 utilizes the training images 162 and the annotations 166 to train a model 168. The model training component 164 may train the model 168 by using any suitable machine training technique (e.g., deep learning techniques). In some implementations, the model training component 164 utilizes the model training process 200, described below in connection with FIG. 2.

The controller 106 may control aspects of the example system 150, in a non-limiting example, to perform at least a portion of the example method 400 described in connection with FIG. 4, as well as any other operations described herein. In some implementations, the controller 106 may control one or more operations of the MRI system, such as the MRI system 100 described in connection with FIG. 1A. Additionally or alternatively, the computing device 104 of FIG. 1A may perform some or all of the functionality of the controller 106. In such implementations, the computing device 104 may be in communication with the controller 106 to exchange information as necessary to achieve useful results.

The controller 106 may be implemented using software, hardware, or a combination thereof. The controller 106 may include at least one processor and a memory (e.g., a processing circuit). The memory may store processor-executable instructions that, when executed by a processor, cause the processor to perform one or more of the operations described herein. The processor may include a microprocessor, an ASIC, an FPGA, a GPU, a TPU, etc., or combinations thereof. The memory may include, but is not limited to, electronic, optical, magnetic, or any other storage or transmission device capable of providing the processor with program instructions. The memory may further include a floppy disk, CD-ROM, DVD, magnetic disk, memory chip, ASIC, FPGA, ROM, RAM, EEPROM, EPROM, flash memory, optical media, or any other suitable memory from which the processor may read instructions. The instructions may include code generated from any suitable computer programming language. The controller 106 may include any or all of the components and perform any or all of the functions of the computer system 700 described in connection with FIG. 7.

The controller 106 may be configured to perform one or more functions described herein. The controller 106 may store or capture one or more subject image 170. The subject image 170 may be an MR image obtained using an MR system, such as the MRI system 100 described in connection with FIG. 1A. Alternatively, the subject image may be a natural image or another type of medical image. Like the training images, the subject image may be a two-, three-, or four-dimensional image. The subject image may also be a one-dimensional projection of a higher dimensional image. The subject image may be isotropic or anisotropic. In some implementations, the subject image 170 may be obtained externally and provided to the controller 106 via one or more communication interfaces. The subject image 170 may be MR images generated using diffusion weighted (DWI), T1 weighted (T1), T2 weighted (T2), or fluid-attenuated inversion recovery (FLAIR) sequence types.

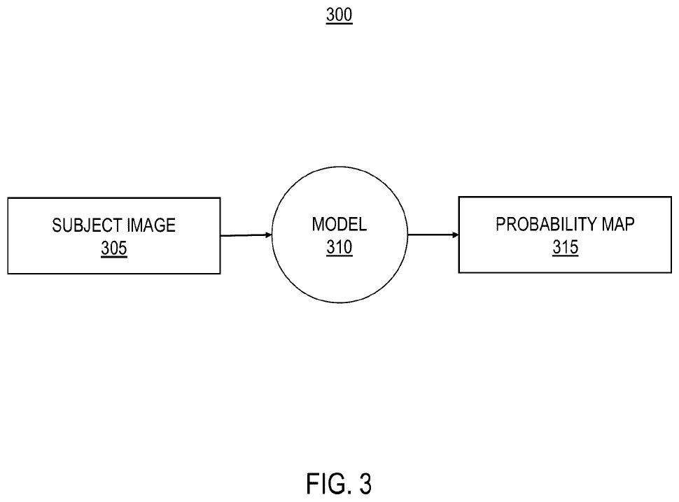

The controller 106 may include a model executor 172. The model executor 172 may execute a model, such as the model 168 (which in some implementations may be stored in memory of the controller 106 or the computing device 104) using the subject image 170 as input to generate a probability map 174. The model executor 172 may execute a model according to the model deployment process 300, described below in connection with FIG. 3.

The probability map 174 may indicate the probability that pixels belong in a particular category. For example, the probability map 174 may indicate the probability that pixels are in the foreground of the subject image 170. In another implementation, the probability map 174 may indicate the probability that pixels are in the foreground of the subject image 170 and that they are in the background of the subject image 170. In another implementation, the probability map 174 may indicate the probability that pixels are in the foreground of the subject image 170, the background of the subject image 170, and/or if they belong to a particular structure or artifact in the foreground or background of the subject image 170. The model 168 may be similar to or may include any of the models described herein. The model executor 172 may execute the model 168 using the subject image 170 as an input to generate a probability map 174.

In some implementations the probability map 174 may be thresholded to produce a mask 178 of the subject image 170. The probability map may be thresholded using any suitable thresholding technique. In certain embodiments, the masks resulting from multiple thresholds may be generated and the resulting masks evaluated in determining which mask to use. In some embodiments, thresholds may be in part based on the annotations 166.

FIG. 2 depicts an example data flow diagram of an example model training process 200 in accordance with one or more implementations. The model training process 200 may be performed by the model training component 164 of the model training system 150 described in connection with FIG. 1B. The model training process 200 has, as inputs, training images 205 and annotations 210. The training images 205 may be the training images 162 of the model training system 150 described in connection with FIG. 1B. The annotations 210 may be the annotations 166 of the model training system 150 described in connection with FIG. 1B.

Using the images 205 and the annotations 210, the model training operation 215 of the model training process 200 may train an initial model using a suitable training technique. The initial model may be a machine-learning model. The machine learning model may comprise a neural network. In one implementation the initial model may comprise a residual neural network-based model. In other implementations, the model may comprise a convolutional neural network, a U-Net neural network, a neural network with attention units, a fully connected neural network, a region-based convolutional neural network (RCNN), a fast RCNN, a transformer type neural network, or a multilayer perceptron neural networks. The initial model may be configured to receive, as an input, an image and provide, as an output, one or more probability maps. In one implementation, the initial model may be configured to receive, as input, an MR image and provide, as output, one or more probability maps indicative of foreground probabilities for pixels in the MR image, wherein a foreground probability for a pixel is indicative of a likelihood that the pixel is in a foreground object or artifact in the image.

The model training operation 215 may include performing a supervised learning process (e.g., stochastic gradient descent and backpropagation, an Adam optimizer, etc.) to adjust the trainable parameters of the initial model to minimize validation loss. The model training operation 215 may be executed iteratively, or over multiple epochs, to minimize validation loss. Any suitable loss function may be utilized to train the initial model, such as an L1 loss, an L2 loss, a mean-squared error (MSE) loss, cross entropy, binary cross entropy (BCE), categorical cross entropy (CC), or sparse categorical cross entropy (SCC) loss functions, among others. The loss may be calculated based on the output of the model when one of the images 205 is provided as input and based on a corresponding one of the annotations 210. Once trained, the resulting model 220 may be output as the model 168 of the model training system 150 described in connection with FIG. 1B. The model 220 may be applied to a subject image to produce one or more probability maps for the subject image, as further described in connection with FIG. 3.

FIG. 3 depicts an example data flow diagram of an example model deployment process 300. The model deployment process 300 may be performed by the model executor 172 of the model training system 150, described in connection with FIG. 1B. The model deployment process 300 has, as an input, a subject image 305. The subject image 305 may be the subject image 170 of the model training system 150, described in relation to FIG. 1B. The model deployment process 300 applies a model 310 to the subject image 305 to generate a probability map 315 of the subject image 305. The model 310 may be the model 168, trained according to the model training process 200, described in accordance with FIG. 2. The resulting probability map 315 may be output as the probability map 174 of the model training system 150, described in connection with FIG. 1B.

FIG. 4 illustrates a flowchart of an example method 400 of training a segmentation model (e.g., the model 168 of FIG. 1B, etc.) and deploying the model to generate a foreground mask of an image. The method 400 may be executed using any suitable computing system (e.g., the training platform 160, the controller 106, or the computing device 104 of FIG. 1, the computing system 700 of FIG. 7, etc.). It will be appreciated that certain steps of the method 400 may be executed in parallel (e.g., concurrently) or sequentially, while still achieving useful results.

The method 400 may include block 410, in which training images and annotations are received. The training images may be the training images 162 of the model training system 150, as described in connection with FIG. 1B. The annotations may be the annotations 166 of the model training system 150, as described in connection with FIG. 1B. In some implementations, the training images received at block 410 of the method 400 are MR images. In some implementations, the MR images may be generated based on a plurality of sequence types. The plurality of sequence types may comprise at least one of DWI, T1, T2, and/or FLAIR sequence types. Alternatively, the plurality of sequence types may comprise a plurality of DWI, T1, T2, and/or FLAIR sequence types. In various embodiments, the training images may comprise non-MR medical images, as well as non-medical images captured using any imaging device (e.g., a camera). In some implementations, the annotations received at block 410 of the method 400 may characterize pixels. For example, the annotations may identify pixels as being in the foreground and/or the background, helping distinguish between pixels in the foreground of the training images and pixels in the background of the images. In some embodiments, the annotations indicate whether a pixel is an object (e.g., a skull of a subject). Additionally or alternatively, annotations may identify artifacts. Artifacts can be due to the MR scanner itself (e.g., hardware or software), the subject being imaged (e.g., tissue heterogeneity), and/or interaction of the subject being imaged with the scanner (e.g., movement by the subject during imaging). Certain artifacts can be reduced or avoided by adjusting imaging parameters. Artifacts, if not identified, may result in false diagnoses or otherwise reduce image quality.

The method 400 may include block 420, in which a model, configured to receive an image as an input and provide one or more probability maps as an output, is generated. The model may be generated based on the received images and annotations. In some implementations the model is generated based on received images and annotations indicative of which pixels are in the foreground of the images and the model may be configured to receive, as input, an image and provide, as output, a probability map indicative of foreground probabilities for pixels in the image. A foreground probability for a pixel is indicative of a likelihood that the pixel is part of a foreground object or artifact in the image. The model may be generated according to any suitable machine-learning (e.g., deep learning) technique. In some implementations, the model is generated by the model training process 200, described in connection with FIG. 2. In some implementations, generating the model may comprise minimizing validation loss over a plurality of iterations, or epochs. The validation loss may be, for example, a cross entropy loss. In some implementations, the model may comprise a neural network. The neural network may be or may comprise a residual neural network-based model.

The method 400 may include block 430, in which a subject image is received. In some implementations, the subject image is an MR image. The subject image may be the subject image 170 of the model training system 150, as described in connection with FIG. 1B.

The method 400 may include block 435, in which a foreground mask for the subject image is generated. In some embodiments, one or more probability maps are generated by applying a machine learning model to an MR image of a subject (e.g., a patient having a head or other body part scanned). The machine learning model may have been generated based on training images and annotations that characterize pixels in the images. The annotations may distinguish between pixels in the foregrounds of the training images and pixels in the backgrounds of the training images. The annotations may be, or may include, for example, a manual selection (e.g., a shape corresponding to a perimeter of a foreground region, and/or one or more objects or artifacts in each image) the machine learning model being configured to receive, as input, the subject MR image and provide, as output, one or more probability maps indicative of foreground probabilities for pixels in the subject MR image, wherein a foreground probability for a pixel is indicative of a likelihood that the pixel is in a foreground structure in the subject MR image. In other implementations, the model is the model generated at block 420 of method 400. In some implementations, the model may be generated according to any suitable machine-learning (e.g., deep learning) technique. In some implementations, the model is generated by the model training process 200, described in connection with FIG. 2. In some implementations, the model may be, or may comprise, a neural network.

In some implementations, generating a foreground mask includes thresholding the probability map indicative of foreground probabilities for pixels in the subject MR image. Thresholding may be achieved by applying any suitable thresholding technique. A threshold may be selected such that, for example, foreground probabilities at least as great as a certain value—for example, a minimum likelihood that a pixel is part of a foreground, object, or artifact, such as above 50%, above 55%, above 60%, above 65%, above 70%, above 75%, above 80%, above 85%, above 90%, above 95%, or above 98%—would place the pixel in the foreground. A resulting foreground mask would exclude pixels with probabilities below the threshold (as part of the background), and include (as part of the foreground, object, artifact, etc.), pixels with probabilities at least as great as the selected threshold. In some implementations, the foreground mask may be a binary foreground mask based on one threshold value, such that pixels with values below the one threshold are in one category (e.g., background, or “0”), whereas pixels at least as great as the threshold are in another category (e.g., foreground, or “1”). In other implementations, a mask may be non-binary. A non-binary mask may be based on, for example, multiple thresholds. In one example, if two thresholds are used, then pixels with values below the first threshold may be assigned a first category (e.g., background, or “0”), values at least as great as the first threshold but less than a second (higher) threshold may be assigned a second category (e.g., foreground, or “1”), and values at least as great as the second threshold may be assigned a third category (e.g., artifact, an object, or “2”). As used herein, an object may be an anatomical structure of a patient being scanned, a medical implant in the patient, etc. In various embodiments, an object may itself be an object of interest, may be an object useful as a reference point for locating an object of interest in an image, or may be an object to be ignored for having little to no diagnostic value.

The method 400 may include a first subroutine 405, comprising blocks 410 and 420, and a second subroutine 425, comprising blocks 430 and 435. The first subroutine 405 and the second subroutine 425 may be executed sequentially in example embodiments. Alternatively, the first subroutine 405 may be executed without executing the second subroutine 425, or the second subroutine 425 may be executed without executing the first subroutine 405. For example, the first subroutine 405 may provide a trained or updated machine learning model, and the second subroutine 425 may deploy a trained or updated machine learning model. If the model is already available, then the first subroutine may be skipped, and the model may be used to analyze images resulting from, for example, medical scans of regions of interest of subjects.

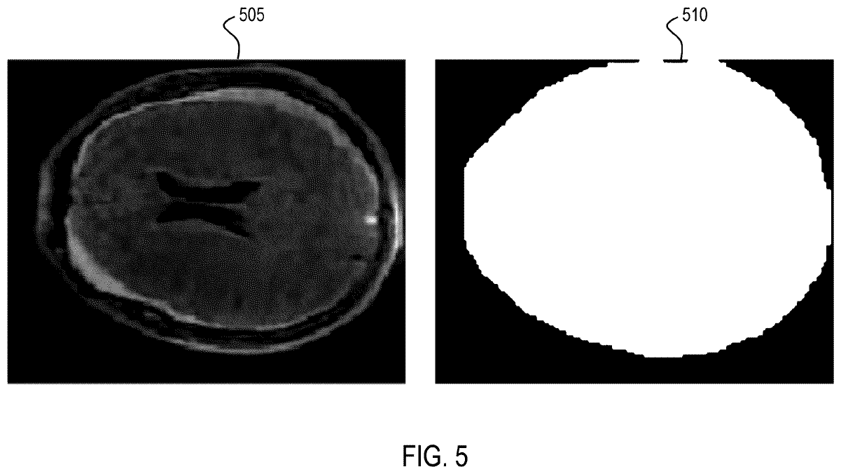

FIG. 5 shows an example foreground mask 510 of an MR image 505, produced in accordance with one or more of the implementations described herein. The MR image 505 has two segments, the foreground (e.g., the object being imaged) and the background (e.g., the empty space in the image). The foreground mask 510 is a binary representation of this segmentation. The pixels in the foreground mask 510 that correspond to the foreground of the MR image 505 may be assigned a value of “1” (i.e., the white space) while those that correspond to the background of the MR image 505 may be assigned a value of “0” (i.e., the black area surrounding the white space).

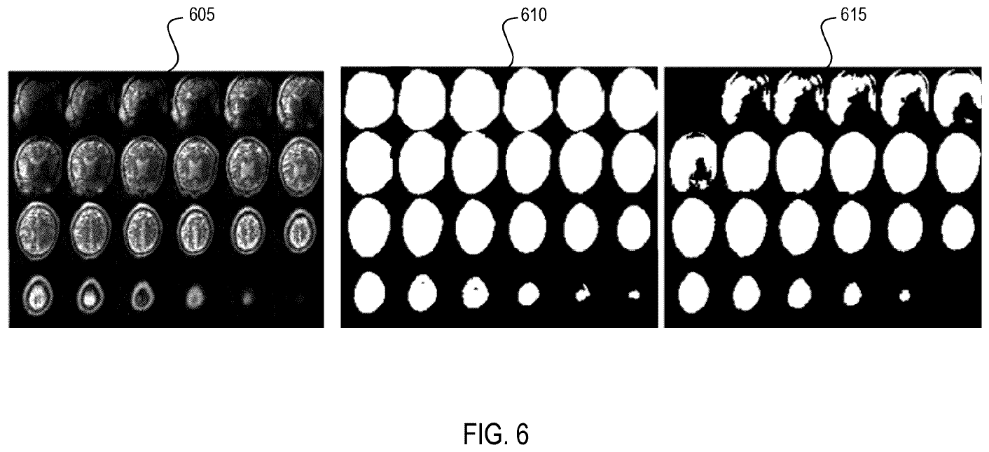

FIG. 6 shows example experimental data comparing foreground mask generation approaches. An MR image 605 was generated based on a T2 pulse sequence. The MR image 605 to be processed may include, for example, a set of slices or cross-sections, generated via MR scans of a subject's head, each of which may include a foreground and a background. A foreground mask 610 was generated from the MR image 605 in accordance with one or more of the implementations described herein. A second foreground mask 615 was generated from the image 605 by a traditional thresholding technique, specifically Otsu's thresholding technique. Otsu's technique calculates an optimal threshold that maximizes the separation between foreground pixels and background pixels based on a histogram of the pixel values of the image. The foreground mask 610 demonstrates superior segmentation accuracy when compared to the second foreground mask 615. In particular, the low intensity foreground pixels of the MR image 605 are properly classified as foreground pixels in the foreground mask 610 while they are incorrectly categorized as background pixels in the second foreground mask 615.

FIG. 7 is a component diagram of an example computing system suitable for use in the various implementations described herein, according to an example implementation. In a non-limiting example, the computing system 700 may implement a computing device 104, the controller 106, or the training platform 160 of FIGS. 1A and 1B, or various other example systems and devices described in the present disclosure.

The computing system 700 includes a bus 702 or other communication component for communicating information and a processor 704 coupled to the bus 702 for processing information. The computing system 700 also includes main memory 706, such as a RAM or other dynamic storage device, coupled to the bus 702 for storing information, and instructions to be executed by the processor 704. Main memory 706 may also be used for storing position information, temporary variables, or other intermediate information during execution of instructions by the processor 704. The computing system 700 may further include a ROM 708 or other static storage device coupled to the bus 702 for storing static information and instructions for the processor 704. A storage device 710, such as a solid-state device, magnetic disk, or optical disk, is coupled to the bus 702 for persistently storing information and instructions.

The computing system 700 may be coupled via the bus 702 to a display 714, such as a liquid crystal display, or active matrix display, for displaying information to a user. An input device 712, such as a keyboard including alphanumeric and other keys, may be coupled to the bus 702 for communicating information, and command selections to the processor 704. In another implementation, the input device 712 has a touch screen display. The input device 712 may include any type of biometric sensor, or a cursor control, such as a mouse, a trackball, or cursor direction keys, for communicating direction information and command selections to the processor 704 and for controlling cursor movement on the display 714.

In some implementations, the computing system 700 may include a communications adapter 716, such as a networking adapter. Communications adapter 716 may be coupled to bus 702 and may be configured to enable communications with a computing or communications network or other computing systems. In various illustrative implementations, any type of networking configuration may be achieved using communications adapter 716, such as wired (e.g., via Ethernet), wireless (e.g., via Wi-Fi, Bluetooth), satellite (e.g., via GPS) pre-configured, ad-hoc, LAN, WAN, and the like.

According to various implementations, the processes of the illustrative implementations that are described herein may be achieved by the computing system 700 in response to the processor 704 executing an implementation of instructions contained in main memory 706. Such instructions may be read into main memory 706 from another computer-readable medium, such as the storage device 710. Execution of the implementation of instructions contained in main memory 706 causes the computing system 700 to perform the illustrative processes described herein. One or more processors in a multi-processing implementation may also be employed to execute the instructions contained in main memory 706. In alternative implementations, hard-wired circuitry may be used in place of or in combination with software instructions to implement illustrative implementations. Thus, implementations are not limited to any specific combination of hardware circuitry and software.

The implementations described herein have been described with reference to drawings. The drawings illustrate certain details of specific implementations that implement the systems, methods, and programs described herein. Describing the implementations with drawings should not be construed as imposing on the disclosure any limitations that may be present in the drawings.

It should be understood that no claim clement herein is to be construed under the provisions of 35 U.S.C. § 112(f), unless the element is expressly recited using the phrase “means for.”

As used herein, the term “circuit” may include hardware structured to execute the functions described herein. In some implementations, each respective “circuit” may include machine-readable media for configuring the hardware to execute the functions described herein. The circuit may be embodied as one or more circuitry components including, but not limited to, processing circuitry, network interfaces, peripheral devices, input devices, output devices, sensors, etc. In some implementations, a circuit may take the form of one or more analog circuits, electronic circuits (e.g., integrated circuits (IC), discrete circuits, system on a chip (SOC) circuits), telecommunication circuits, hybrid circuits, and any other type of “circuit.” In this regard, the “circuit” may include any type of component for accomplishing or facilitating achievement of the operations described herein. In a non-limiting example, a circuit as described herein may include one or more transistors, logic gates (e.g., NAND, AND, NOR, OR, XOR, NOT, XNOR), resistors, multiplexers, registers, capacitors, inductors, diodes, wiring, and so on.

The “circuit” may also include one or more processors communicatively coupled to one or more memory or memory devices. In this regard, the one or more processors may execute instructions stored in the memory or may execute instructions otherwise accessible to the one or more processors. In some implementations, the one or more processors may be embodied in various ways. The one or more processors may be constructed in a manner sufficient to perform at least the operations described herein. In some implementations, the one or more processors may be shared by multiple circuits (e.g., circuit A and circuit B may comprise or otherwise share the same processor, which, in some example implementations, may execute instructions stored, or otherwise accessed, via different areas of memory). Alternatively or additionally, the one or more processors may be structured to perform or otherwise execute certain operations independent of one or more co-processors.

In other example implementations, two or more processors may be coupled via a bus to enable independent, parallel, pipelined, or multi-threaded instruction execution. Each processor may be implemented as one or more general-purpose processors, ASICs, FPGAs, GPUs, TPUs, digital signal processors (DSPs), or other suitable electronic data processing components structured to execute instructions provided by memory. The one or more processors may take the form of a single core processor, multi-core processor (e.g., a dual core processor, triple core processor, or quad core processor), microprocessor, etc. In some implementations, the one or more processors may be external to the apparatus, in a non-limiting example, the one or more processors may be a remote processor (e.g., a cloud-based processor). Alternatively or additionally, the one or more processors may be internal or local to the apparatus. In this regard, a given circuit or components thereof may be disposed locally (e.g., as part of a local server, a local computing system) or remotely (e.g., as part of a remote server such as a cloud based server). To that end, a “circuit” as described herein may include components that are distributed across one or more locations.

An example system for implementing the overall system or portions of the implementations might include general purpose computing devices in the form of computers, including a processing unit, a system memory, and a system bus that couples various system components including the system memory to the processing unit. Each memory device may include non-transient volatile storage media, non-volatile storage media, non-transitory storage media (e.g., one or more volatile or non-volatile memories), etc. In some implementations, the non-volatile media may take the form of ROM, flash memory (e.g., flash memory such as NAND, 3D NAND, NOR, 3D NOR), EEPROM, MRAM, magnetic storage, hard discs, optical discs, etc. In other implementations, the volatile storage media may take the form of RAM, TRAM, ZRAM, etc. Combinations of the above are also included within the scope of machine-readable media. In this regard, machine-executable instructions comprise, in a non-limiting example, instructions and data, which cause a general-purpose computer, special purpose computer, or special purpose processing machines to perform a certain function or group of functions. Each respective memory device may be operable to maintain or otherwise store information relating to the operations performed by one or more associated circuits, including processor instructions and related data (e.g., database components, object code components, script components), in accordance with the example implementations described herein.

It should also be noted that the term “input devices,” as described herein, may include any type of input device including, but not limited to, a keyboard, a keypad, a mouse, joystick, or other input devices performing a similar function. Comparatively, the term “output device,” as described herein, may include any type of output device including, but not limited to, a computer monitor, printer, facsimile machine, or other output devices performing a similar function.

It should be noted that although the diagrams herein may show a specific order and composition of method steps, it is understood that the order of these steps may differ from what is depicted. In a non-limiting example, two or more steps may be performed concurrently or with partial concurrence. Also, some method steps that are performed as discrete steps may be combined, steps being performed as a combined step may be separated into discrete steps, the sequence of certain processes may be reversed or otherwise varied, and the nature or number of discrete processes may be altered or varied. The order or sequence of any element or apparatus may be varied or substituted according to alternative implementations. Accordingly, all such modifications are intended to be included within the scope of the present disclosure as defined in the appended claims. Such variations will depend on the machine-readable media and hardware systems chosen and on designer choice. It is understood that all such variations are within the scope of the disclosure. Likewise, software and web implementations of the present disclosure could be accomplished with standard programming techniques with rule-based logic and other logic to accomplish the various database searching steps, correlation steps, comparison steps, and decision steps.

While this specification contains many specific implementation details, these should not be construed as limitations on the scope of any inventions or of what may be claimed, but rather as descriptions of features specific to particular implementations of the systems and methods described herein. Certain features that are described in this specification in the context of separate implementations may also be implemented in combination in a single implementation. Conversely, various features that are described in the context of a single implementation may also be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements, and features discussed only in connection with one implementation are not intended to be excluded from a similar role in other implementations.

The phraseology and terminology used herein is for the purpose of description and should not be regarded as limiting. The use of “including,” “comprising,” “having,” “containing,” “involving,” “characterized by,” “characterized in that,” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act, or element may include implementations where the act or element is based at least in part on any information, act, or element.

Any implementation disclosed herein may be combined with any other implementation, and references to “an implementation,” “some implementations,” “an alternate implementation,” “various implementation,” “one implementation,” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The foregoing description of implementations has been presented for purposes of illustration and description. It is not intended to be exhaustive or to limit the disclosure to the precise form disclosed, and modifications and variations are possible in light of the above teachings or may be acquired from this disclosure. The implementations were chosen and described in order to explain the principals of the disclosure and its practical application to enable one skilled in the art to utilize the various implementations and with various modifications as are suited to the particular use contemplated. Other substitutions, modifications, changes, and omissions may be made in the design, operating conditions and implementation of the implementations without departing from the scope of the present disclosure as expressed in the appended claims.

What is claimed is:

1. A method comprising:
receiving images and annotations indicative of which pixels are in the foregrounds of the images; and
generating, based on the images and the annotations, a machine learning model configured to receive, as input, an image and provide, as output, one or more probability maps indicative of foreground probabilities for pixels in the image, wherein a foreground probability for a pixel is indicative of a likelihood that the pixel is part of a foreground object or artifact in the image.

2. The method of claim 1, wherein generating the machine learning model comprises minimizing validation loss over a plurality of epochs.

3. The method of claim 2, wherein the validation loss is a cross-entropy loss.

4. The method of claim 1, wherein the annotated images comprise annotated magnetic resonance (MR) images generated based on a plurality of sequence types.

5. The method of claim 4, wherein the plurality of sequence types comprises at least one of diffusion-weighted imaging (DWI), T1, T2, or fluid attenuated inversion recovery (FLAIR).

6. The method of claim 4, wherein the plurality of sequence types comprises a plurality of DWI, T1, T2, and/or FLAIR.

7. The method of claim 1, further comprising deploying the machine learning model to generate a foreground mask for a subject image.

8. The method of claim 7, wherein deploying the machine learning model comprises applying the machine learning model to the subject image, and thresholding foreground probabilities for pixels in the subject image to obtain the foreground mask.

9. The method of claim 1, wherein generating the machine learning model comprises applying a machine learning technique to the images and the annotations, and optimizing a parameter of the machine learning model.

10. The method of claim 1, wherein the machine learning model comprises a neural network.

11. The method of claim 10, wherein the neural network is a residual neural network-based model.

12. A method comprising:
receiving a subject image; and
generating a foreground mask for the subject image at least in part by applying a machine learning model to the subject image, the machine learning model having been generated based on training images and annotations distinguishing between pixels in the foregrounds of the training images and pixels in the backgrounds of the training images, the machine learning model being configured to receive, as input, the subject image and provide, as output, a probability map indicative of foreground probabilities for pixels in the subject image, wherein a foreground probability for a pixel is indicative of a likelihood that the pixel is part of a foreground object or artifact in the subject image.

13. The method of claim 12, wherein generating the foreground mask further comprises thresholding foreground probabilities for pixels in the image to obtain the foreground mask.

14. The method of claim 12, wherein the foreground mask is a binary foreground mask.

15. The method of claim 12, wherein the machine learning model comprises a neural network.
